(19) United States
(12) Patent Application Publication
(10) Pub. No.: US 2012/0097103 A1
(43) Pub. Date: Apr. 26, 2012

(54) PHYSICAL VAPOR DEPOSITION DEVICE FOR COATING WORKPIECE

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 13/037,129

(22) Filed: Feb. 28, 2011

(30) Foreign Application Priority Data
Oct. 26, 2010 (TW) 99136433

(51) Int. Cl. C23C 16/458

(52) U.S. Cl. 118/722

(57) ABSTRACT

A physical vapor deposition device includes a deposition chamber, a workpiece carrier received in the deposition chamber, a plurality of plate-shaped inner targets, and a plurality of plate-shaped outer targets. The workpiece carrier rotates about a rotation axis thereof. The workpiece carrier includes an inner carrier, and an outer carrier fixed relative to the inner carrier. The outer carrier surround the inner carrier. The inner targets are arranged between the inner carrier and the outer carrier. The outer targets surround the outer carrier.

### BACKGROUND

1. Technical Field

The present disclosure relates to a physical vapor deposition device for coating workpiece.

2. Description of Related Art

Physical vapor deposition (PVD) devices are widely used to form functional or decorative metallic films on workpieces. A typical PVD device usually includes a deposition chamber, a deposition carrier and a number of targets positioned in the deposition chamber. The deposition carrier is a single assembly with a number of posts for supporting a number of workpieces. The targets are positioned on opposite sides of the deposition carrier, face to face.

However, because of the small distance between the two opposite targets, the two opposite targets will easily influence each other. Thus, the deposition quality of the workpieces will be influenced.

Therefore, a physical vapor deposition device which can overcome the above-mentioned problems is desired.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is an isometric view of a physical vapor deposition device including a workpiece carrier according to an exemplary embodiment.

FIG. 2 is a top planer view of the physical vapor deposition device of FIG. 1.

FIG. 3 is a cutaway view of the workpiece carrier of FIG. 1.

FIG. 4 is a cross-section of the workpiece carrier of FIG. 3.

### DETAILED DESCRIPTION

Embodiments will now be described in detail below with reference to the drawings.

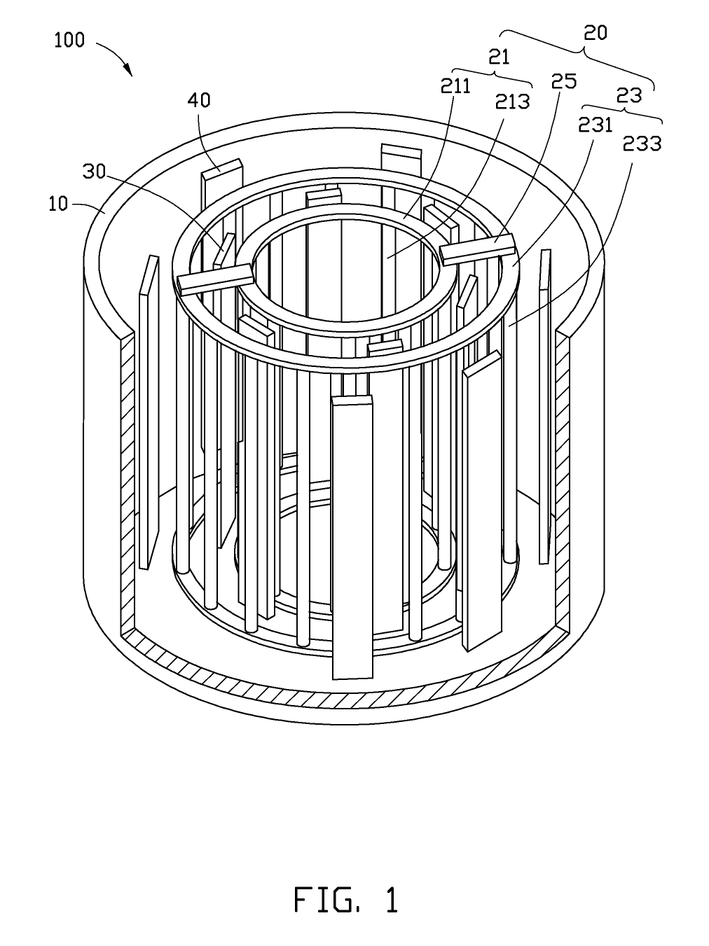

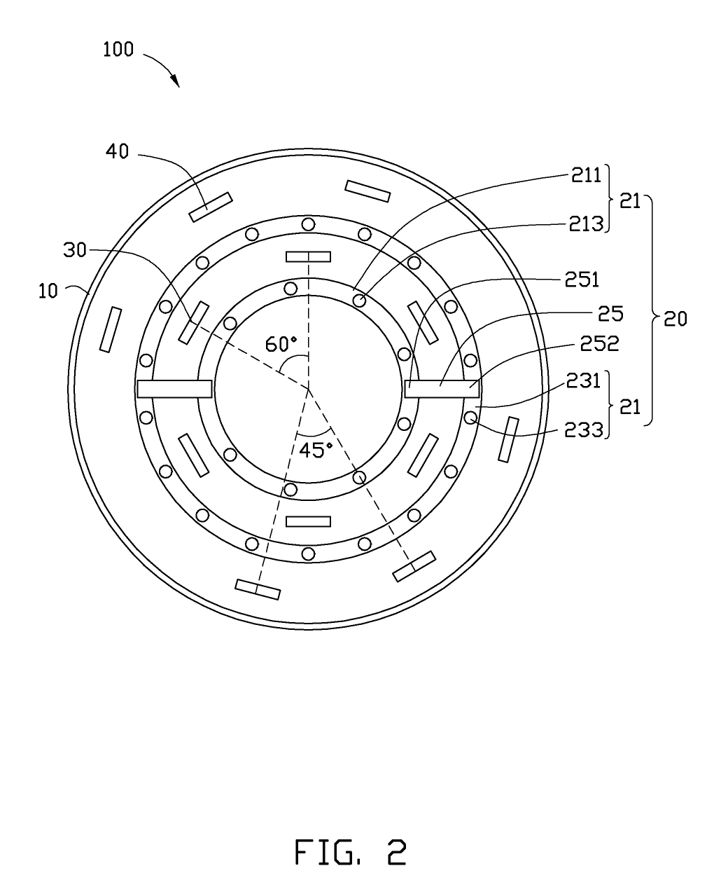

Referring to FIGS. 1-2, a physical vapor deposition device 100 for coating workpieces in accordance with an exemplary embodiment is provided. The physical vapor deposition device 100 includes a deposition chamber 10, a workpiece carrier 20, six inner targets 30, and six outer targets 40.

The deposition chamber 10 is a vacuum chamber. All of the following, the workpiece carrier 20, the three inner targets 30, and the six outer targets 40 are in the deposition chamber 10.

The workpiece carrier 20 is received in the deposition chamber 10, and able to rotate around a rotation axis. The workpiece carrier 20 includes an inner carrier 21, an outer carrier 23, and two connecting arms 25. In this embodiment, the workpiece carrier 20 is located at the central area of the deposition chamber 10. The rotation axis of the workpiece carrier 20 and the central axis of the deposition chamber 10 are coaxial to each other. The inner carrier 21 and the outer carrier 23 are used for supporting workspieces. The connecting arms 25 fixedly fasten the inner carrier 21 and the outer carrier 23.

The inner carrier 21 has an inner annular frame 211, and a number of inner posts 213. The inner posts 213 extend from the inner annular frame 211, and are substantially parallel to each other. In this embodiment, the inner posts 213 are mounted on the inner annular frame 211 with uniform intervals. Each of the inner posts 213 is able to rotate around its central axis.

The outer carrier 23 has an outer annular frame 231, and a number of outer posts 233. The outer posts 233 extend from the outer annular frame 231, and are substantially parallel to each other. In this embodiment, the outer posts 233 are mounted on the outer annular frame 231 with uniform intervals. Each of the outer posts 233 is able to rotate around its central axis.

The inner carrier 21 and the outer carrier 23 are concentric with the rotation axis. The inner carrier 21 is inside the outer carrier 23. The outer posts 233 of the outer carrier 23 surround the inner carrier 21. Each of the outer posts 233 and the inner posts 213 are substantially parallel to each other, and substantially parallel to the rotation axis of the workpiece carrier 20.

The connecting arms 25 are used to fixedly fasten the inner carrier 21 and the outer carrier 23. Therefore, the inner carrier 21 and the outer carrier 23 can simultaneously rotate around the rotation axis. In this embodiment, the connecting arms 25 are located on the top of the inner carrier 21 and the outer carrier 23, opposite to each other. The connecting arms 25 are between the inner carrier 21 and the outer carrier 23, fastening the inner carrier 21 and the outer carrier 23. Each of the connecting arms 25 has a first end 251, and a second end 252 opposite to the first end 251. The first end 251 is fastened to the inner annular frame 211 of the inner carrier 21. The second end 252 is fastened to the outer annular frame 231 of the outer carrier 23. Therefore, the inner carrier 21 and the outer carrier 23 cooperatively form the workpiece carrier 20.

The connecting arms 25 can fasten the inner carrier 21 and the outer carrier 23 with bolts and nuts, or pins and holes, or other mechanisms.

Each of the inner targets 30 and the outer targets 40 is plate-shaped, and used for supporting a deposition source. In this embodiment, each lengthwise direction of the inner targets 30 and the outer targets 40 is substantially parallel to the central axis of the workpiece carrier 20.

The six inner targets 30 and the six outer targets 40 are arranged in a staggered fashion along a circumferential direction of the outer carrier 23. The six inner targets 30 are arranged along an imaginary circle and located at the central area between the inner carrier 21 and the outer carrier 23, and surround the rotation axis of the workpiece carrier 20 with uniform intervals. The central angle between every two adjacent inner targets 30 is 60 degrees. The six outer targets 40 are arranged along an imaginary circle and located outside the outer carrier 23, and surround the outer carrier 23. The six outer targets 40 includes two first outer targets 40 arranged along a first diametrical direction, two second outer targets 40 arranged along a second diametrical direction perpendicular to the first diametrical direction, two third outer targets 40 arranged along a third diametrical direction oriented at 45 degrees with respect to the first diametrical direction. That is, the six outer targets 40 are delivered into two groups. The two groups are symmetrical with each other, and each includes three outer targets 40. The central angle between each two adjacent outer targets 40 in the same group is 45 degrees.

In other embodiments, the physical vapor deposition device 100 can include four or eight or more inner targets 30 at the central area between the inner carrier 21 and the outer carrier 23, and four, eight or more outer targets 40 outside the outer carrier 23.

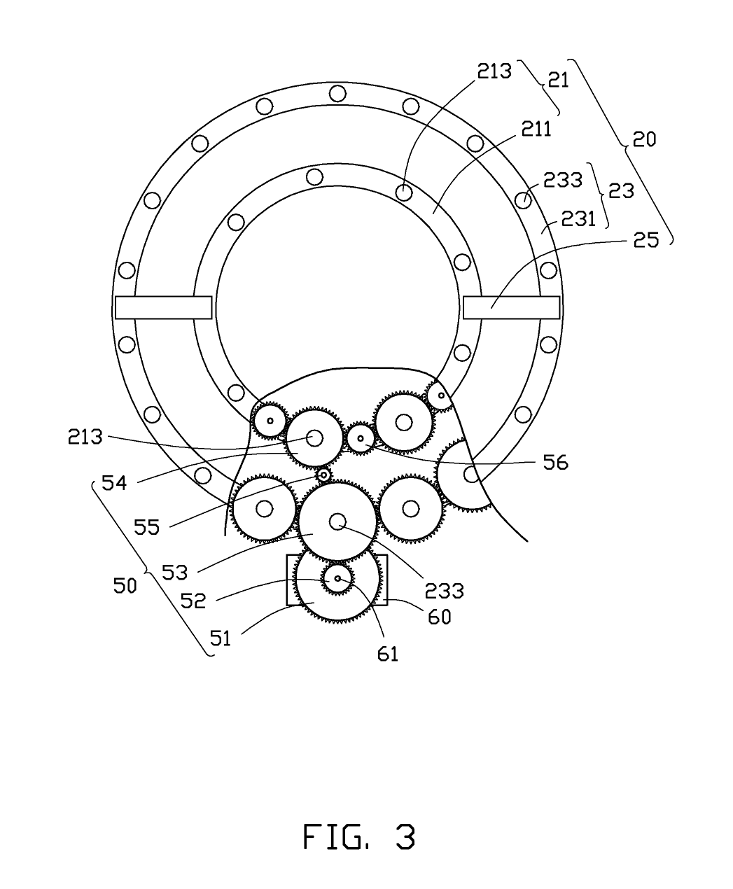

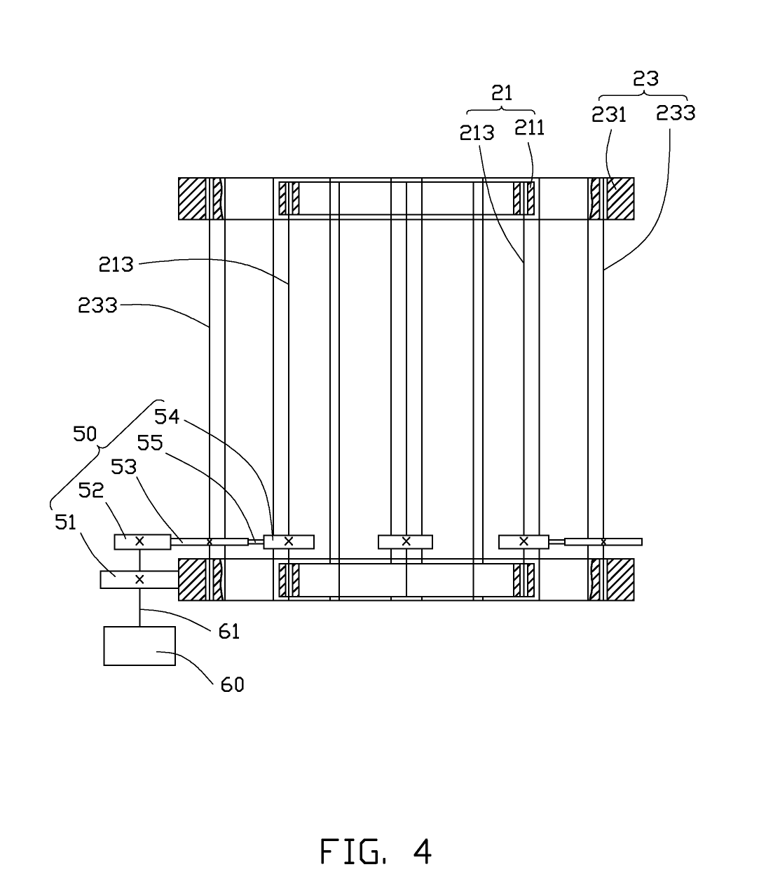

Referring to FIGS. 3-4, the physical vapor deposition device 100 further includes a gear transmission mechanism 50, and a drive member 60. The gear transmission mechanism 50 engages with the inner carrier 21 and the outer carrier 23, and is driven by the drive member 60. Therefore, the workpiece carrier 20 can be driven to rotate around the rotation axis, and each of the inner posts 213 and the outer posts 233 can be driven to rotate around its own axis.

In this embodiment, the gear transmission mechanism 50 is equipped to the workpiece carrier 20, and located in the bottom of the workpiece carrier 20. The gear transmission 50 includes a first drive gear 51, a second drive gear 52, a plurality of first slave gears 53 and second slave gears 54, a first idler gear 55, and a plurality of second idler gears 56. The drive member 60 includes a motor (not shown) having a drive shaft 61. The first drive gear 51 and the second drive gear 52 are fixedly coupled to the drive shaft 61. The first slave gears 53 are fixedly coupled to the respective outer posts 233. The second slave gears 54 are fixedly coupled to the respective inner posts 213. The first drive gear 51 engages with the teeth (see FIG. 4) formed on circumferential periphery of the outer annular frame 231 of the outer carrier 23. The second drive gear 52 engages with a first slave gear 53 coupled to one of the outer posts 233. The first slave gear 53 engages the second slave gear 54 with the first idler gear 55. Every two adjacent first slave gears 53 directly engage with each other. Every two adjacent second slave gears 54 engage with each other with one of the second idler gear 56. The gear ratio between the first drive gear 51 and the outer carrier 23 is different from the gear ratio between the second drive gear 52 and the first slave gear 53. Therefore, the drive member 60 can effectively drive the inner carrier 21 and the outer carrier 23 to simultaneously rotate around the rotation axis, and each of the inner posts 213 and outer posts 233 to rotate around its own axis.

It is to be understood that in alternative embodiments, a belt transmission mechanism or a chain transmission mechanism can be equipped to the workpiece carrier 20.

In operation, the drive member 60 drives the workpiece carrier 20 to rotate around the rotation axis, each of the inner posts 213 and outer posts 233 rotates around its own central axis. Therefore, the workpieces supported on the inner posts 213 and the outer posts 233 can face the deposition sources on the inner targets 30 and the outer targets 40 in different directions. Accordingly, the deposition angel of the workpieces can be adjusted. Finally, the resultant material from the deposition source is deposited onto the workpieces from different direction.

Due to the inner targets 30 and the outer targets 40 staggeredly arranged around a circumferential direction of the workpiece carrier 20, the opposite surfaces between different targets can be greatly reduced. Therefore, the physical vapor deposition device 100 can greatly reduce the possibility of influence between different targets. Because of the inner carrier 21 and the outer carrier 23 being concentric to each other, the physical vapor deposition device 100 can have more posts arranged for supporting more workpieces. Therefore, the yield of the deposited workpieces can be substantially increased.

It is to be understood that the above-described embodiments are intended to illustrate rather than limit the disclosure. Variations may be made to the embodiments without departing from the spirit of the disclosure. The above-described embodiments illustrate the scope of the disclosure but do not restrict the scope of the disclosure.

What is claimed is:

1. A physical vapor deposition device, comprising:
a deposition chamber; and
a workpiece carrier received in the deposition chamber, and being rotatable about a rotation axis thereof; the workpiece carrier comprising an inner carrier, and an outer carrier fixed relative to the inner carrier, the outer carrier surrounding the inner carrier;
a plurality of plate-shaped inner targets arranged between the inner carrier and the outer carrier, and
a plurality of plate-shaped outer targets surrounding the outer carrier.

2. The physical vapor deposition device of claim 1, wherein the inner targets and the outer targets are arranged in a staggered fashion along a circumferential direction of the outer carrier.

3. The physical vapor deposition device of claim 2, wherein the inner targets consist of six equidistantly spaced inner targets along an imaginary circle.

4. The physical vapor deposition device of claim 2, wherein the outer targets consist of six outer targets arranged along an imaginary circle, the six outer targets including two first outer targets arranged along a first diametrical direction, two second outer targets arranged along a second diametrical direction perpendicular to the first diametrical direction, two third outer targets arranged along a third diametrical direction oriented at 45 degrees with respect to the first diametrical direction.

5. The physical vapor deposition device of claim 1, wherein the workpiece carrier further comprises two connecting arms, the two connecting arms are located on opposite sides of the inner carrier.

6. The physical vapor deposition device of claim 5, wherein the inner carrier is fixed relative to the outer carrier by means of the connecting arms.

7. The physical vapor deposition device of claim 1, wherein each of the inner carrier and the outer carrier includes a plurality of posts substantially parallel to each other, each of the posts is parallel to the rotation axis of the workpiece carrier, and rotatable about a central axis thereof.

8. The physical vapor deposition device of claim 7, further comprising a transmission mechanism, wherein the transmission mechanism engages with the inner carrier and the outer carrier.

9. The physical vapor deposition device of claim 8, wherein the transmission mechanism includes a first drive gear, a second drive gear, a plurality of first slave gears coupled to the respective posts arranged on the outer carrier, a plurality of second slave gears coupled to the respective posts arranged on the inner carrier, and at least one idler gear meshed with one of the first slave gears and one of the second slave gears.

10. The physical vapor deposition device of claim 9, further comprising a drive member for driving the gear transmission mechanism.

11. The physical vapor deposition device of claim 10, wherein the drive member includes a motor having a drive shaft, the first and second drive gears are coupled to the drive shaft, the first drive gear engages with the outer carrier, the second drive gear engages with one of the first slave gears.

12. The physical vapor deposition device of claim 11, wherein the gear ratio between the first drive gear and the outer carrier is different from the gear ratio between the second drive gear and the first slave gear.

13. A physical vapor deposition device comprising:
a deposition chamber;
a workpiece carrier received in the deposition chamber, and being rotatable about a rotation axis thereof; the workpiece carrier comprising:
an inner carrier having a inner annular frame, and a plurality of inner posts extending from the inner frame, the inner carrier including a plurality of teeth formed on the circumferential periphery of the inner frame;
an outer carrier surrounding the inner carrier, the outer carrier having an outer annular frame, and a plurality of outer posts extending from the outer frame;
a connecting member fixedly interconnected between the inner and outer frame;
a drive assembly comprising:
a plurality of first slave gears fixedly coupled to the respective outer posts, each two adjacent first slave gears meshed with each other;
a plurality of second slave gears fixedly coupled to the respective inner posts;
a first idler gear meshed with one of the first slave gears and one of the second slave gears;
a plurality of second idler gears each meshed with and between each two adjacent second slave gears;
a motor having a drive shaft;
a first drive gear meshed with the teeth of the first carrier; and
a second drive gear meshed with one of the first slave gears, the first and second drive gears fixedly coupled to the drive shaft;
a plurality of plate-shaped inner targets between the inner carrier and the outer carrier; and
a plurality of plate-shaped outer targets surrounding the outer carrier.

14. The physical vapor deposition device of claim 13, wherein the connecting member comprises two connecting arms, the two connecting arms are located on opposite sides of the inner carrier.

15. The physical vapor deposition device of claim 14, wherein the inner carrier is fixed relative to the outer carrier by means of the connecting arms.

16. The physical vapor deposition device of claim 13, wherein the inner targets and the outer targets are arranged in a staggered fashion along a circumferential direction of the outer carrier.

17. The physical vapor deposition device of claim 16, wherein the inner targets consist of six equidistantly spaced inner targets along an imaginary circle.

18. The physical vapor deposition device of claim 16, wherein the outer targets consist of six outer targets arranged along an imaginary circle, the six outer targets including two first outer targets arranged along a first diametrical direction, two second outer targets arranged along a second diametrical direction perpendicular to the first diametrical direction, two third outer targets arranged along a third diametrical direction oriented at 45 degrees with respect to the first diametrical direction.

19. The physical vapor deposition device of claim 13, wherein the gear ratio between the first drive gear and the outer carrier is different from the gear ratio between the second drive gear and the first slave gear.
